(19) United States
(12) Patent Application Publication
(10) Pub. No.: US 2014/0197447 A1
(43) Pub. Date: Jul. 17, 2014

(54) LIGHT EMITTING DEVICE

(71) Applicants: Masaharu Kitano, Osaka-shi (JP); Takehiro Shiomoto, Osaka-shi (JP); Hideshi Koizumi, Osaka-shi (JP)

(72) Inventors: Masaharu Kitano, Osaka-shi (JP); Takehiro Shiomoto, Osaka-shi (JP); Hideshi Koizumi, Osaka-shi (JP)

(73) Assignee: SHARP KABUSHIKI KAISHA, Osaka-shi, Osaka (JP)

(21) Appl. No.: 14/238,099

(22) PCT Filed: Aug. 6, 2012
(86) PCT No.: PCT/JP2012/069990

§ 371 Date: Feb. 10, 2014

(30) Foreign Application Priority Data
Aug. 23, 2011 (JP) 2011-181665

(51) Int. Cl. H01L 33/62

(52) U.S. Cl. CPC H01L 33/62
USPC 257/99

(57) ABSTRACT

The light emitting device (10A) includes an LED chip (12) and a ceramic support body (14) where the LED chip (12) is placed. The ceramic support body (14) includes a placement surface (14d) where the LED chip (12) is placed, internal terminals (22a, 22b) disposed on the placement surface (14d), a back surface (14c) that face the placement surface (14d), a mounting surface (14b) between the placement surface (14d) and the back surface (14c), and external terminals (28a, 28b) disposed on the mounting surface (14b). The internal terminals (22a, 22b) are coupled to the external terminals (28a, 28b) through at least one inner via (24a, 24b).

### TECHNICAL FIELD

The present invention relates to a light emitting device that includes a light emitting element and a support body as a package substrate on which the light emitting element is placed.

### BACKGROUND ART

Along with the recent improvement of efficiency, LEDs have been widely used as an energy-saving light source compared with light bulbs and fluorescent lights. Nowadays, the development of blue LEDs has proceeded and white LEDs where a blue LED and a phosphor are combined are also put into practical use. The white LED is used as a light source of a small-sized liquid-crystal backlight unit for mobile terminals and similar product. In particular, in order to ensure thinner mobile terminals and similar product, a liquid-crystal backlight unit using a light emitting device of side-emission type has been developed. The light emitting device of side-emission type applied to the liquid-crystal backlight unit is arranged at the back side of a liquid crystal panel so as to face a light-guiding plate. Lights are introduced from the end surface to the light-guiding plate in this configuration. In this case, the light emitting device of side-emission type, the light-guiding plate, and a mounting board on which the light emitting device is mounted constitute a plane light source for the liquid-crystal backlight unit.

The above-described light emitting device of side-emission type has an advantage of ensuring a thinned liquid-crystal backlight unit. Accordingly, nowadays, this light emitting device is used in a medium-sized liquid-crystal backlight unit of a laptop personal computer or similar product or in a large-sized liquid-crystal backlight unit of a liquid crystal television or similar product. Along with the increase in size of the liquid-crystal backlight unit, a light source with higher luminance is required. Furthermore, it is also necessary to satisfy the requirements of lower cost compared with the current light sources such as fluorescent tubes. To realize replacement of the light source from the fluorescent tubes, a large number of LEDs need to be mounted on the mounting board.

FIG. 7 illustrates an example of the conventional light emitting device of side-emission type.

A light emitting device 100 illustrated in FIG. 7 includes a bottom surface as a mounting surface, and emits a light irradiated by a light emitting element 120 from its front surface. A light emitting element mounting substrate 110 includes, on its front surface, an opening depressed portion 130 for placing the light emitting element 120. This depressed portion 130 includes lead electrodes 131a and 131b. The light emitting element mounting substrate 110 includes groove portions 112a and 112b formed by cutting out respective parts of both sides facing each other in a width direction on the bottom surface such that a region near the center in the width direction remains on the bottom surface.

The lead electrodes 131a and 131b are a pair of inner leads for coupling to the light emitting element 120, and are formed of metal films. These metal films (the lead electrodes) 131a and 131b are formed such that respective end surfaces are exposed on outer surface at the bottom surface side. The respective end surfaces of the metal films 131a and 131b are exposed on inner surfaces of the groove portions 112a and 112b. Furthermore, the inner surfaces of the groove portions 112a and 112b are coated with respective metal films 132a and 132b. An electrical conduction (continuous structure) is provided each of between the metal films 131a and 132a and between the metal films 131b and 132b.

Accordingly, soldering in the positions of the groove portions 112a and 112b on a mounting board (not illustrated) forms the light emitting device 100 of side-emission type in which the mounting board is electrically conductive to the metal films (the lead electrodes) 131a and 131b within the depressed portion 130 via the metal films 132a and 132b of the groove portions 112a and 112b.

The metal films 132a and 132b are portions over which solder is applied at the time of soldering the light emitting device 100 to the mounting board. The metal films 132a and 132b are formed such that the state of solder wetting can be checked from the outside in the mounted state.

Here, although illustration is omitted, the light emitting element mounting substrate 110 is formed by laminating a reflector layer with a cavity hole (a first support body 2 in FIG. 3 of Patent Document 1) and a film forming layer with the metal films 132a and 132b (a first support body 1 in FIG. 3 of Patent Document 1). In the case where the package is made of ceramic material, these members are integrated after firing as illustrated in FIG. 7.

### PRIOR ART DOCUMENT

### Patent Document

Patent Document 1: Japanese Unexamined Patent Application Publication No. 2011-91344

### SUMMARY OF INVENTION

### Problem to be Solved by the Invention

A conduction method by forming metal films as disclosed in Patent Document 1 described above has various problems as follows.

When the reflector layer and the film forming layer are laminated together, metal films are formed thin at the corner portions of the light emitting element mounting substrate 110. Furthermore, the metal films may be separated in these corner portions. Accordingly, the metal films may be coupled to (continuous with) one another only in some portions and it may be difficult to provide an electrical conduction by contact between the respective metal films 131a and 131b of the inner leads and the respective metal films 132a and 132b of the outer leads.

The metal film may be in a disconnected state, for example, due to thermal expansion and contraction or due to leaching, expansion, and contraction that occur during soldering in the metal film or the substrate constituent material. Accordingly, the metal films are disconnected and this makes power feeding to the light emitting element difficult. A consequent problem is that non-lighting of the light emitting element occurs.

As illustrated in metal films 31a, 31b, and 32 and similar film in FIG. 3 of Patent Document 1, the metal films are not continuously formed in the corner portions. Therefore, soldering in this state may cause leaching and disconnection of the metal due to the solder.

The metal film in the groove portion may be pulled to the mounting surface side of the light emitting device on the mounting board by solder, and disconnection may occur in the corner portion.

The present invention has been made in view of the above-described various problems occurring mainly in the corner portions of the light emitting element mounting substrate. An object of the present invention is to provide a light emitting device that prevents disconnection between the inner leads (inner lead terminals) and the outer leads (outer lead terminals) and prevents disconnection of the metal films in the substrate corner portions.

### Means for Solving the Problems

To solve the above-described problems, a light emitting device of the present invention is a light emitting device that includes a light emitting element and a support body where the light emitting element is placed. The support body includes a placement surface where the light emitting element is placed, an internal terminal disposed on the placement surface, a back surface that face the placement surface, a mounting surface disposed on a surface between the placement surface and the back surface, and an external terminal disposed on the mounting surface. The internal terminal is coupled to the external terminal through at least one inner via. Additionally, the internal terminal includes an internal anode terminal and an internal cathode terminal The internal anode terminal and the internal cathode terminal are coupled to the light emitting element. The external terminal includes an external anode terminal and an external cathode terminal. The internal anode terminal is coupled to the external anode terminal through the inner via for anode terminal. The internal cathode terminal is coupled to the external cathode terminal through the inner via for cathode terminal.

With the above-described configuration, the internal terminal and the external terminal are coupled together through the inner via. This prevents disconnection between the internal terminal and the external terminal and solves the problem of non-lighting of the light emitting device.

Additionally, according to the present invention, a back-surface terminal is disposed on the back surface. The back-surface terminal is coupled to the external terminal. The internal terminal is coupled to the back-surface terminal through at least one inner via. Additionally, the internal terminal includes an internal anode terminal and an internal cathode terminal. The internal anode terminal and the internal cathode terminal are coupled to the light emitting element. The external terminal includes an external anode terminal and an external cathode terminal The back-surface terminal includes a back-surface anode terminal and a back-surface cathode terminal. The internal anode terminal is coupled to the back-surface anode terminal through the inner via for anode terminal. The internal cathode terminal is coupled to the back-surface cathode terminal through the inner via for cathode terminal.

With the above-described configuration, the internal terminal and the external terminal are coupled together via the inner via and the back-surface terminal. This prevents disconnection between the internal terminal and the back-surface terminal and between the internal terminal and the external terminal. Additionally, this solves the problem of non-lighting of the light emitting device.

Additionally, according to the present invention, a back-surface terminal may be formed on the back surface coupled to the external terminal. The internal terminal, the back-surface terminal, and the external terminal may each have an end surface that is partially depressed to an inside of the end surface. This configuration reduces occurrence of, for example, delamination, burr, or lifting of metal films of the back-surface terminal, the internal terminal, and the external terminal as much as possible when a plurality of light emitting devices formed on a base substrate is cut to be separated into individual light emitting devices.

Additionally, according to the present invention, the light emitting element is mounted to have a light emitting surface perpendicular to a mounting board. This allows fabricating a light emitting device of side-emission type. Additionally, the light emitting element is mounted to have a light emitting surface parallel to a mounting board. This allows fabricating a light emitting device of top emission type.

The support body is preferred to be formed of ceramic material. Forming the support body using ceramic material improves heat resistance and reliability as a light emitting device.

### Effects of the Invention

According to the present invention, the internal terminal is coupled through the inner via to the back-surface terminal coupled to the external terminal. This prevents disconnection between the internal terminal and the external terminal, and this prevents or reduces occurrence of defects due to non-lighting of the light emitting device.

### BRIEF DESCRIPTION OF DRAWINGS

FIG. 1 is a perspective view conceptually illustrating a light emitting device according to Embodiment 1 in a state where a light emitting surface faces upward.

FIG. 2 is a perspective view conceptually illustrating a light emitting device according to Embodiment 1 in a state mounted on a mounting board such that the light emitting surface faces the far side of the paper.

FIG. 3 is a perspective view conceptually illustrating the light emitting device according to Embodiment 1 in a state mounted on the mounting board such that the light emitting surface faces upward.

FIG. 4 is a perspective view conceptually illustrating a light emitting device according to Embodiment 2 in a state where a light emitting surface faces upward.

FIG. 5 is a perspective view conceptually illustrating the light emitting device according to Embodiment 2 in a state mounted on a mounting board such that the light emitting surface faces the far side of the paper.

FIG. 6 is a perspective view conceptually illustrating the light emitting device according to Embodiment 2 in a state mounted on the mounting board such that the light emitting surface faces upward.

FIG. 7 is a schematic diagram of a conventional light emitting device.

### MODE FOR CARRYING OUT THE INVENTION

Embodiments of the present invention will be described below by referring to the accompanying drawings.

### Embodiment 1

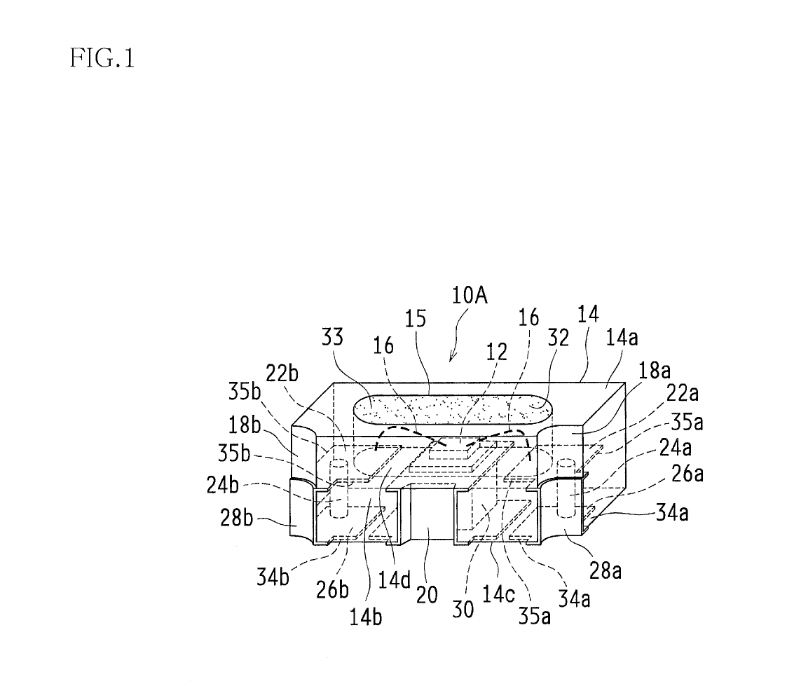

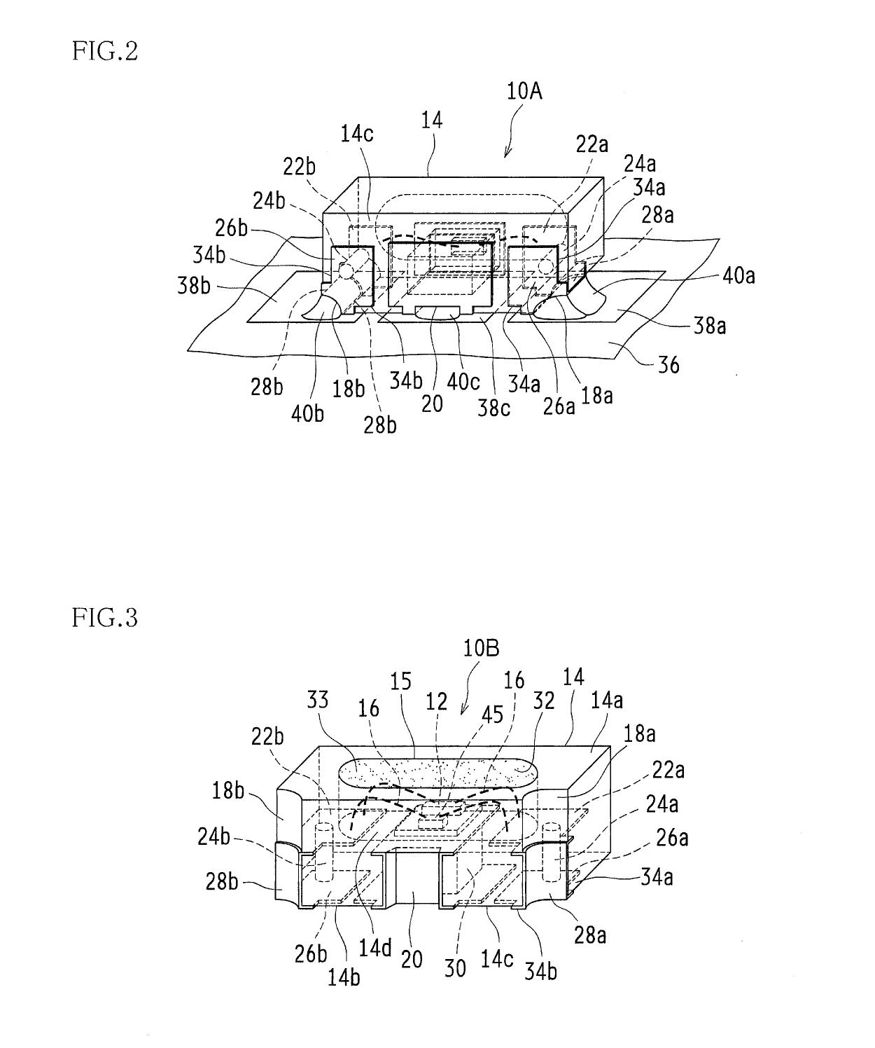

A description will be given of a light emitting device 10A according to Embodiment 1 with reference to FIG. 1 and FIG. 2. FIG. 1 and FIG. 2 are perspective views of a light emitting device according to Embodiment 1. FIG. 2 is a perspective view illustrating a part of a mounting board on which the light emitting device is mounted.

The light emitting device 10A according to Embodiment 1 includes an LED chip 12 and a ceramic support body 14 on which the LED chip 12 is placed.

The ceramic support body 14 is a support body formed approximately in a rectangular parallelepiped shape, and includes one surface (the top surface in FIG. 1) on which a depressed portion for chip 32 is formed. In the depressed portion for chip 32, the LED chip 12 is located. The ceramic support body 14 includes an opening surface 14a, a mounting surface 14b, and a back surface 14c. The opening surface 14a includes an opening 15 of the depressed portion for chip 32. The mounting surface 14b are located to be adjacent to the opening surface 14a and to face a mounting board 36 (see FIG. 2). The back surface 14c is disposed on the opposite side of the opening surface 14a. Both the opening surface 14a and the back surface 14c are formed perpendicular to the mounting surface 14b.

The opening 15 of the depressed portion for chip 32 is formed, for example, in an oval shape. On a placement surface 14d, which is the bottom surface of the depressed portion for chip 32, a heat-conductive member for placement 30 is disposed. The LED chip 12 is placed on the heat-conductive member for placement 30. The heat-conductive member for placement 30 is exposed to the outside at the mounting surface 14b side, and includes an exposed portion formed in a depressed portion 20 that is stepped down from the mounting surface 14b.

On the placement surface 14d, an internal terminal (an internal anode terminal) 22a and an internal terminal (an internal cathode terminal) 22b are placed. The internal anode terminal 22a, the internal cathode terminal 22b, and the heat-conductive member for placement 30 are arranged to be separated (electrically insulated) from one another.

The depressed portion for chip 32 is filled with a phosphor-containing resin 33. Accordingly, the LED chip 12 is coated with the phosphor-containing resin 33. The phosphor-containing resin 33 employs, for example, silicone resin in which phosphor is dispersed.

The phosphor can preferably employ, for example, BOSE (Ba, O, Sr, Si, and Eu). Other than BOSE, the phosphor can preferably employ, for example, SOSE (Sr, Ba, Si, O, and Eu), YAG (Ce-activated yttrium, aluminum, and garnet), a sialon ((Ca), Si, Al, O, N, and Eu), or β sialon (Si, Al, O, N, and Eu).

A P-side electrode and an N-side electrode, which are a pair of pad electrodes, are formed on the surface of the LED chip 12 although illustration is omitted. The P-side electrode is wire-bonded to the internal anode terminal 22a by a wire 16. The N-side electrode is wire-bonded to the internal cathode terminal 22b by a wire 16.

The LED chip 12 employs, for example, a gallium-nitride-based semiconductor light emitting element that can emit a blue-colored light.

On the back surface 14c facing the placement surface 14d of the ceramic support body 14, a back surface electrode (a back-surface anode terminal) 26a is placed in a position facing the internal anode terminal 22a, and a back surface electrode (a back-surface cathode terminal) 26b is placed in a position facing the internal cathode terminal 22b. Furthermore, at one corner portion (the right-side end portion in FIG. 1) of the mounting surface 14b, an external terminal (an external anode terminal) 28a is placed. At another corner portion (the left-side end portion in FIG. 1), an external terminal (an external cathode terminal) 28b is placed.

The external anode terminal 28a and the external cathode terminal 28b are disposed on respective surfaces of depressed portions 18a and 18b formed in an arc shape in the respective corner portions of the mounting surface 14b. The depressed portions 18a and 18b extend from respective ends on the opening surface 14a side to respective ends on the back surface 14c side. Within the depressed portions 18a and 18b, the external anode terminal 28a and the external cathode terminal 28b are disposed from respective ends at the placement surface 14d side to the respective ends on the back surface 14c side. That is, the external anode terminal 28a and the external cathode terminal 28b are formed up to respective height positions to be coupled to the internal anode terminal 22a and the internal cathode terminal 22b.

The internal anode terminal 22a is a thin metal layer, and is formed as a wiring pattern. The internal anode terminal 22a is coupled to the external anode terminal 28a disposed on the mounting surface 14b of the ceramic support body 14. More specifically, the internal anode terminal 22a is disposed to extend along the placement surface 14d inside of the ceramic support body 14 in the lateral direction. The internal anode terminal 22a extends up to the depressed portion 18a of the corner portion. In this corner portion, the internal anode terminal 22a and the external anode terminal 28a are coupled together.

On the other hand, the back-surface anode terminal 26a is disposed to extend along the back surface 14c in the lateral direction. The back-surface anode terminal 26a extends up to the depressed portion 18a in the corner portion. In this corner portion, the back-surface anode terminal 26a and the external anode terminal 28a are coupled together. That is, the internal anode terminal 22a, the external anode terminal 28a, and the back-surface anode terminal 26a are coupled together to have a U-shaped vertical cross section.

In this coupling structure, in this embodiment, an inner via 24a for anode terminal is further formed so as to electrically couple the internal anode terminal 22a and the back-surface anode terminal 26a together.

The internal cathode terminal 22b is a thin metal layer, and is formed as a wiring pattern. The internal cathode terminal 22b is coupled to the external cathode terminal 28b disposed on the mounting surface 14b of the ceramic support body 14. More specifically, the internal cathode terminal 22b is disposed to extend along the placement surface 14d inside of the ceramic support body 14 in the lateral direction. The internal cathode terminal 22b extends up to the depressed portion 18b in the corner portion. In this corner portion, the internal cathode terminal 22b and the external cathode terminal 28b are coupled together.

On the other hand, the back-surface cathode terminal 26b is disposed to extend along the back surface 14c in the lateral direction. The back-surface cathode terminal 26b extends up to the depressed portion 18b of the corner portion. In this corner portion, the back-surface cathode terminal 26b and the external cathode terminal 28b are coupled together. That is, the internal cathode terminal 22b, the external cathode terminal 28b, and the back-surface cathode terminal 26b are coupled together to have a U-shaped vertical cross section.

In this coupling structure, in this embodiment, an inner via 24b for cathode terminal is further formed so as to electrically couple the internal cathode terminal 22b and the back-surface cathode terminal 26b.

The inner vias 24a and 24b are via holes formed to penetrate from the placement surface 14d to the back surface 14c in the ceramic support body 14. The inner vias 24a and 24b are formed by filling the inside of the via (hole) with conductive material so as not to cause disconnection from the placement surface 14d to the back surface 14c. This structure is similar in the following embodiments. While in this Embodiment 1 the inner vias 24a and 24b are formed to be buried in the ceramic support body 14, the inner vias 24a and 24b may be formed immediately below the placement surface 14d.

As illustrated in FIG. 2, in the light emitting device 10A with this configuration, the external anode terminal 28a and the external cathode terminal 28b are coupled to respective land patterns 38a and 38b for electrode formed on the mounting board 36 via brazing materials 40a and 40b. Additionally, the heat-conductive member for placement 30 is coupled to a land pattern 38c formed on the mounting board 36 via a brazing material 40c. That is, in the mounted state, the brazing materials 40a, 40b, and 40c that secure the ceramic support body 14 to the mounting board 36 are filled in the respective depressed portions 18a and 18b and depressed portion 20.

Accordingly, the LED chip 12 is electrically coupled to wiring (not illustrated) on the mounting board 36 via the internal anode terminal 22a, the inner via 24a, the back-surface anode terminal 26a, the external anode terminal 28a, and brazing material 40a. The LED chip 12 is electrically coupled to the other wiring (not illustrated) of the mounting board 36 via the internal cathode terminal 22b, the inner via 24b, the back-surface cathode terminal 26b, the external cathode terminal 28b, and brazing material 40b. That is, power is reliably fed to the LED chip 12 via the brazing materials 40a and 40b. This reduces the problem of non-lighting of the light emitting device 10A. Furthermore, bringing an inspection terminal into contact with the back-surface anode terminal 26a and the back-surface cathode terminal 26b in an inspection process facilitates examining the characteristics of the light emitting device 10A.

Incidentally, in the case where the light emitting device 10A is fabricated, although illustration is omitted, a single ceramic base material is used to fabricate a large number of light emitting devices 10A on the ceramic base material at once. Subsequently, this ceramic base material is cut to be separated into the individual light emitting devices 10A. At that time, as illustrated in FIG. 1, at the back-surface anode terminal 26a and the back-surface cathode terminal 26b, respective depressions 34a and 34b as cut margins, that is, respective cut-out portions are disposed. The cut-out portions are inwardly stepped down from the surface of the ceramic support body 14. Additionally, at the internal anode terminal 22a and the internal cathode terminal 22b, respective depressions 35a and 35b are disposed as cut margins, that is, cut-out portions are inwardly stepped down from the surface of the ceramic support body 14. This ensures a structure insusceptible to cutting of the light emitting device 10A.

This reduces occurrence of, for example, delamination, burr, or lifting of the metal film during cutting as much as possible regarding the back-surface terminals (the back-surface anode terminal 26a and the back-surface cathode terminal 26b), the internal terminals (the internal anode terminal 22a and the internal cathode terminal 22b), and the external terminals (the external anode terminal 28a and the external cathode terminal 28b).

Furthermore, bonding between the inner via 24a and the back-surface anode terminal 26a and bonding between the inner via 24b and the back-surface cathode terminal 26b increases mechanical strengths and adhesive strengths of the back-surface anode terminal 26a and the back-surface cathode terminal 26b at the back surface 14c. This further reduces delamination and lifting of the back-surface anode terminal 26a or the back-surface cathode terminal 26b during cutting.

Accordingly, this reduces non-lighting defects of the light emitting device 10A due to the electrical coupling.

The internal cathode terminal 22a is coupled to the external anode terminal 28a via the back-surface anode terminal 26a through the inner via 24a. The internal cathode terminal 22b is coupled to the external cathode terminal 28b via the back-surface cathode terminal 26b through the inner via 24b. Accordingly, the internal anode terminal 22a and the internal cathode terminal 22b can be reliably coupled to the wiring on the mounting board 36. That is, the inner vias 24a and 24b can ensure reliability of the electrical coupling.

### Embodiment 2

FIG. 3 is a perspective view of a light emitting device 10B according to Embodiment 2 of the present invention.

The light emitting device 10B according to Embodiment 2 differs from the light emitting device 10A according to Embodiment 1 in that a zener diode 45 that protects the LED chip 12 is mounted together with the LED chip 12 on the placement surface 14d of the ceramic support body 14.

The light emitting device 10B according to Embodiment 2 is otherwise similar to the light emitting device 10A according to Embodiment 1 illustrated in FIG. 1. Therefore, here, like reference numerals designate corresponding or identical elements in the drawings, and such elements will not be further elaborated here.

### Embodiment 3

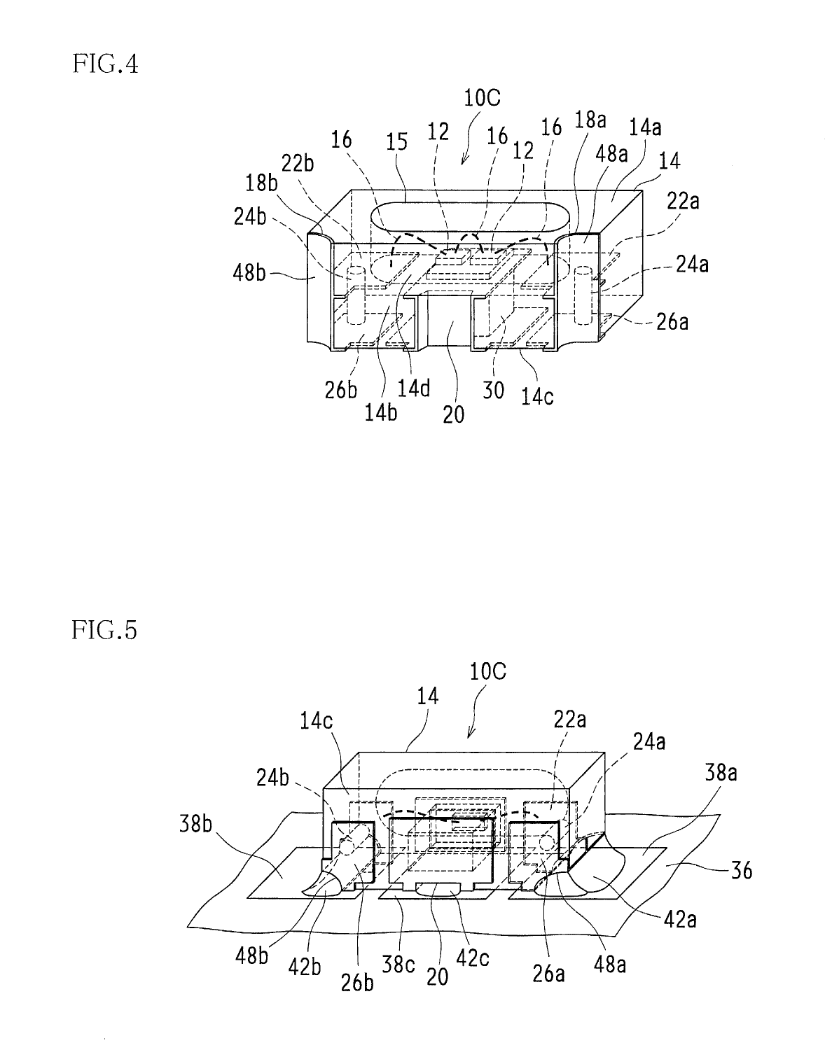

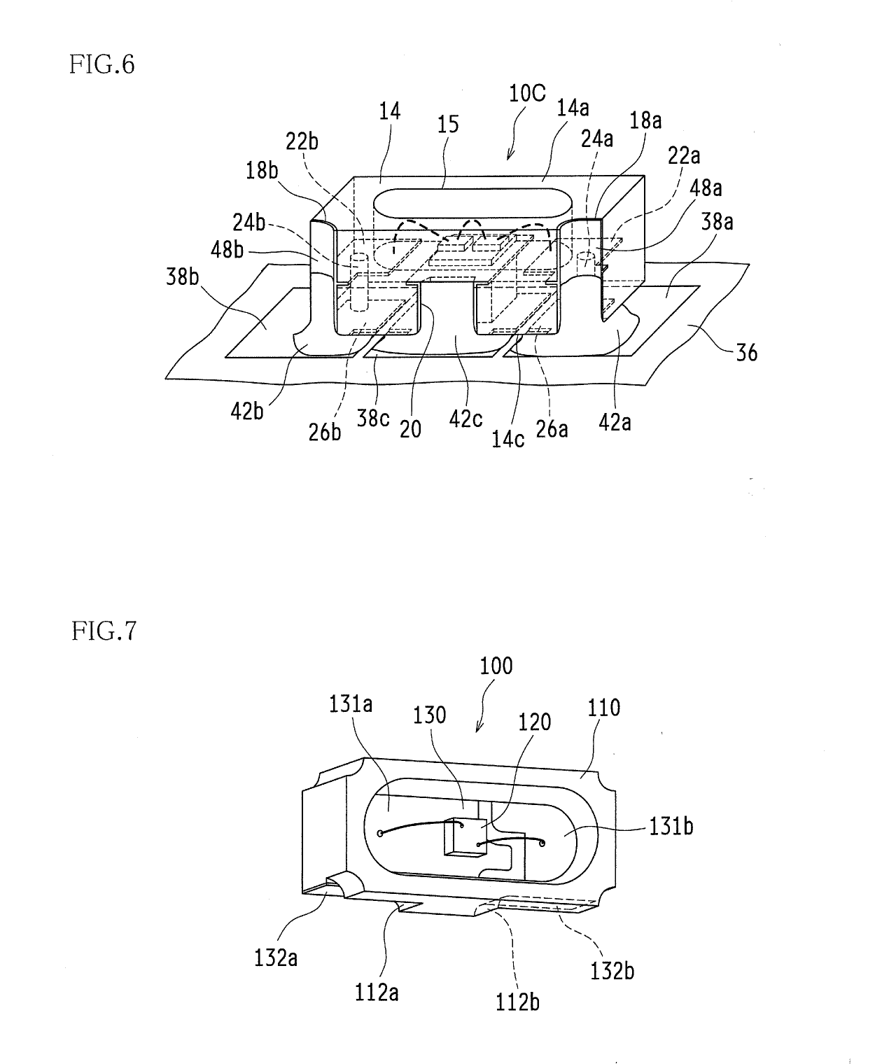

FIG. 4 to FIG. 6 are perspective views of a light emitting device according to Embodiment 3. FIG. 5 and FIG. 6 illustrate a part of a mounting board on which the light emitting device is mounted for convenience. The following describes a light emitting device 10C according to Embodiment 3 with reference to FIG. 4 to FIG. 6.

The light emitting device 10C according to Embodiment 3 differs from the light emitting device 10A according to Embodiment 1 in that two LED chips 12 are coupled in series and placed on the placement surface 14d of the ceramic support body 14. Additionally, respective external anode terminal 48a and external cathode terminal 48b are integrally formed over the entire length of the depressed portions 18a and 18b from the respective ends on the opening surface 14a side to the respective ends on the back surface 14c side.

The light emitting device 10C according to Embodiment 3 is otherwise similar to the light emitting device 10A according to Embodiment 1 illustrated in FIG. 1. Therefore, here, like reference numerals designate corresponding or identical elements in the drawings, and such elements will not be further elaborated here.

FIG. 5 illustrates a configuration where the light emitting device 10C according to Embodiment 3 is mounted on the mounting board 36. Similarly to FIG. 2, the light emitting device 10C is mounted as a light emitting device of side-emission type. In this case, in the light emitting device 10C, the external anode terminal 48a and the external cathode terminal 48b are formed over the entire length from the respective ends on the opening surface 14a side to the respective ends on the back surface 14c side within the depressed portions 18a and 18b. This increases the area coupled to the mounting board 36 (specifically, the land patterns 38a and 38b for electrode) via brazing materials 42a and 42b, thus stably mounting the light emitting device 10C on the mounting board 36.

The shapes of the external anode terminal 48a and the external cathode terminal 48b are also applicable to the external anode terminal 28a and the external cathode terminal 28b in Embodiment 1 and Embodiment 2.

FIG. 6 illustrates another configuration where the light emitting device 10C according to Embodiment 3 is mounted on the mounting board 36. In this example, the light emitting device 10C is mounted as a light emitting device of top emission type in which the back surface 14c of the ceramic support body 14 is arranged facing the mounting board 36 and the opening surface (a light emitting surface) 14a of the ceramic support body 14 is arranged facing upward.

While in Embodiments 1 to 3 described above each one of the inner via 42a for anode terminal and the inner via 42b for cathode terminal are disposed, each two or more inner vias may be disposed for anode terminal and cathode terminal.

The internal terminal and the back-surface terminal are formed to be electrically conductive by the inner via. Accordingly, the external terminal may be formed to be electrically conductive only to one of the internal terminal and the back-surface terminal. The external terminal has the configuration electrically conductive only to one of the internal terminal and the back-surface terminal in order to minimize the number of processes when these terminals are formed by electrolytic plating.

The above-described exemplary embodiments are to all intents and purposes merely illustrative and should not be construed as limiting. The scope of the present invention is defined by the claims and is not in any way restricted by the descriptions of the specification. Furthermore, all variations within the meaning and range of equivalency of the claims fall within the scope of the present invention.

### DESCRIPTION OF REFERENCE SIGNS

10A to 10C light emitting device
12 LED chip (light emitting element)
14 ceramic support body (support body)
14a opening surface (light emitting surface)
14b mounting surface
14c back surface
14d placement surface
15 opening
16 wire
18a, 18b depressed portion
22a internal terminal (internal anode terminal)
22b internal terminal (internal cathode terminal)
24a, 24b inner via
26a back-surface terminal (back-surface anode terminal)
26b back-surface terminal (back-surface cathode terminal)
28a, 48a external terminal (external anode terminal)
28b, 48b external terminal (external cathode terminal)
30 heat-conductive member for placement
32 depressed portion for chip
33 phosphor-containing resin
34a, 34b, 35a, 35b depression (cut-out portion)
36 mounting board
38a, 38b, 38c land pattern
40a, 40b, 40c, 42a, 42b, 42c brazing material

1. A light emitting device, comprising:
a light emitting element; and
a support body where the light emitting element is placed, wherein the support body includes:
a placement surface where the light emitting element is placed;
a back surface that face the placement surface; and
a mounting surface on a surface of the support body, the mounting surface being disposed between the placement surface and the back surface, wherein
the placement surface includes an internal terminal, and the mounting surface includes an external terminal, and
the internal terminal is coupled to the external terminal through at least one inner via.

2. The light emitting device according to claim 1, wherein
the internal terminal includes an internal anode terminal and an internal cathode terminal, the internal anode terminal and the internal cathode terminal being coupled to the light emitting element,
the external terminal includes an external anode terminal and an external cathode terminal,
the internal anode terminal is coupled to the external anode terminal through the inner via for anode terminal, and
the internal cathode terminal is coupled to the external cathode terminal through the inner via for cathode terminal.

3. The light emitting device according to claim 1, wherein
a back-surface terminal is disposed on the back surface, the back-surface terminal being coupled to the external terminal, and
the internal terminal is coupled to the back-surface terminal through at least one inner via.

4. The light emitting device according to claim 3, wherein
the internal terminal includes an internal anode terminal and an internal cathode terminal, the internal anode terminal and the internal cathode terminal being coupled to the light emitting element,
the external terminal includes an external anode terminal and an external cathode terminal,
the back-surface terminal includes a back-surface anode terminal and a back-surface cathode terminal,
the internal anode terminal is coupled to the back-surface anode terminal through the inner via for anode terminal, and
the internal cathode terminal is coupled to the back-surface cathode terminal through the inner via for cathode terminal.

5. The light emitting device according to claim 3, wherein
the internal terminal, the back-surface terminal, and the external terminal each have an end surface that is partially depressed to an inside of the end surface.

6. The light emitting device according to claim 1, wherein
the light emitting element is mounted to have a light emitting surface perpendicular to a mounting board.

7. The light emitting device according to claim 1, wherein
the light emitting element is mounted to have a light emitting surface parallel to a mounting board.

8. The light emitting device according to claim 1, wherein the support body is formed of ceramic material.

9. The light emitting device according to claim 6, wherein the support body is formed of ceramic material.

10. The light emitting device according to claim 7, wherein the support body is formed of ceramic material.
